(19) United States
(12) Patent Application Publication
(10) Pub. No.: US 2025/0266080 A1
(43) Pub. Date: Aug. 21, 2025

(54) INTEGRATED CIRCUIT READING DATA AND SEMICONDUCTOR DEVICE INCLUDING THE SAME

(71) Applicant: SAMSUNG ELECTRONICS CO., LTD, Suwon-si (KR)

(72) Inventors: Geonho KIM, Suwon-si (KR); Kyeong Keun Kang, Suwon-si (KR); Shinyoung Yi, Suwon-si (KR); Kwanyeob Chae, Suwon-si (KR)

(73) Assignee: SAMSUNG ELECTRONICS CO., LTD, Suwon-si (KR)

(21) Appl. No.: 19/029,920

(22) Filed: Jan. 17, 2025

(30) Foreign Application Priority Data
Feb. 21, 2024 (KR) 10-2024-0025338
Apr. 12, 2024 (KR) 10-2024-0049641

(51) Int. Cl. G11C 11/4076; G11C 11/4096

(52) U.S. Cl. CPC G11C 11/4076; G11C 11/4096

(57) ABSTRACT

Provided is a semiconductor device including: a logic die; and a memory device connected to the logic die, the logic die including: a deserializer configured to output first parallel data based on input data received from the memory device using a first clock signal having a first phase and output second parallel data based on the input data using a second clock signal having a second phase, the first phase differing from the second phase; and a first-in first-out circuit configured to: sample the first parallel data using the second clock signal and store the sampled first parallel data as first sampling data, sample the second parallel data using the second clock signal and store the sampled second parallel data as second sampling data, output the first and second sampling data as first and second output data in response to a rising edge of a memory clock signal.

### CROSS-REFERENCE TO RELATED APPLICATIONS

This application is based on and claims priority to Korean Patent Application Nos. 10-2024-0025338, filed on Feb. 21, 2024, and 10-2024-0049641, filed on Apr. 12, 2024, in the Korean Intellectual Property Office, the disclosures of which are incorporated herein by reference in their entireties.

### BACKGROUND

### 1. Field

The disclosure relates to an integrated circuit configured to read data and a semiconductor device including the same.

### 2. Description of Related Art

With the growing demand for high-speed data processing in semiconductor memory devices, high-bandwidth memory (HBM) devices are being used to facilitate high-speed data transfers.

In order for a controller of an HBM to read data from a memory die, a first-in first-out (FIFO) circuit is required.

When the FIFO circuit of the HBM operates based on a single-phase clock signal, both a rising edge and a falling edge of the clock signal should be used to read data output from the memory die in a double data rate (DDR) scheme.

Therefore, a duty of the clock signal should be maintained at a constant level to perform a stable read operation of the HBM.

However, the clock signal input to the FIFO circuit should be distributed to each of a plurality of through-silicon vias (TSVs) connected to a memory die. As an electrical distance for distributing the clock signal increases, there is the increasing likelihood that the duty of the clock signal is not maintained.

### SUMMARY

Provided is a semiconductor device for stably reading data using clock signals having different phases.

According to an aspect of the disclosure, a semiconductor device includes: a logic die; and a memory device connected to the logic die, wherein the logic die includes: a deserializer configured to output first parallel data based on input data received from the memory device using a first clock signal having a first phase and output second parallel data based on the input data using a second clock signal having a second phase, wherein the first phase is different from the second phase; and a first-in first-out (FIFO) circuit configured to: sample the first parallel data using the second clock signal and store the sampled first parallel data as first sampling data, sample the second parallel data using the second clock signal and store the sampled second parallel data as second sampling data, output the first sampling data as first output data in response to a rising edge of a memory clock signal, and output the second sampling data as second output data in response to the rising edge of the memory clock signal.

According to an aspect of the disclosure, an integrated circuit includes: a deserializer configured to output first parallel data based on input data using a first clock signal having a first phase and output second parallel data based on the input data using a second clock signal having a second phase, wherein the first phase is different from the second phase; a delay circuit configured to delay the second clock signal by a first delay time and output a first delay clock signal; and a first-in first-out (FIFO) circuit configured to: sample the first parallel data in response to a rising edge of the first delay clock signal and store the sampled first parallel data as first sampling data, sample the second parallel data in response to the rising edge of the first delay clock signal and store the sampled second parallel data as second sampling data, output the first sampling data as first output data in response to a rising edge of a memory clock signal, and output the second sampling data as second output data in response to the rising edge of the memory clock signal.

According to an aspect of the disclosure, a semiconductor device includes: a logic die; and a plurality of memory dies stacked on one surface of the logic die and configured to operate using a plurality of clock signals having different phases, wherein the logic die includes: a deserializer configured to output first parallel data based on input data received from the plurality of memory dies using a first clock signal having a first phase and output second parallel data from the input data using a second clock signal having a second phase, wherein the first phase is different from the second phase; a delay circuit configured to delay the second clock signal by a first delay time and output a first delay clock signal; and a first-in first-out (FIFO) circuit configured to: sample the first parallel data in response to a rising edge of the first delay clock signal and store the sampled first parallel data as first sampling data, sample the second parallel data in response to the rising edge of the first delay clock signal and store the sampled second parallel data as second sampling data, and output the first sampling data as first output data and output the second sampling data as second output data in response to a rising edge of a memory clock signal in a FIFO scheme.

### BRIEF DESCRIPTION OF DRAWINGS

The above and other aspects and features of certain embodiments of the present disclosure will be more apparent from the following description taken in conjunction with the accompanying drawings, in which:

FIG. 1A is a perspective view illustrating a semiconductor device according to an embodiment of the disclosure;

FIG. 1B is a plan view illustrating a first surface of a logic die of FIG. 1A;

FIG. 1C is a diagram illustrating a plurality of clock signals having different phases;

FIG. 2 is a block diagram illustrating a configuration of a semiconductor device according to an embodiment of the disclosure;

FIG. 3A is a circuit diagram illustrating an integrated circuit configured to read data according to an embodiment of the disclosure;

FIG. 3B is a diagram illustrating data output through the integrated circuit of FIG. 3A;

FIG. 4 is a circuit diagram illustrating a configuration of a delay circuit of FIG. 3A;

FIG. 5 is a circuit diagram illustrating an integrated circuit reading data according to an embodiment of the disclosure;

FIG. 6 is a diagram illustrating data output through the integrated circuit of FIG. 5;

FIG. 7A is a circuit diagram illustrating an integrated circuit configured to read data according to an embodiment of the disclosure;

FIG. 7B is a circuit diagram illustrating an integrated circuit further including a fifth flip-flop in the configuration of FIG. 7A;

FIG. 8 is a diagram illustrating data output through the integrated circuit of FIG. 7A;

FIG. 9 is a circuit diagram illustrating a semiconductor device according to an embodiment of the disclosure;

FIG. 10 is a circuit diagram illustrating an integrated circuit including an input/output circuit configured to obtain data read from a memory device according to an embodiment of the disclosure; and

FIG. 11 is a circuit diagram illustrating an integrated circuit including an input/output circuit configured to exchange data with a memory device according to an embodiment of the disclosure.

### DETAILED DESCRIPTION

Hereinafter, example embodiments will be described with reference to the accompanying drawings.

The terms, such as “first,” “second,” or the like, may represent various elements regardless of order and/or importance. Such terms may only be used to distinguish one element from another element, and do not limit the order and/or importance of the elements.

In the following description, like reference numerals refer to like elements throughout the specification. Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

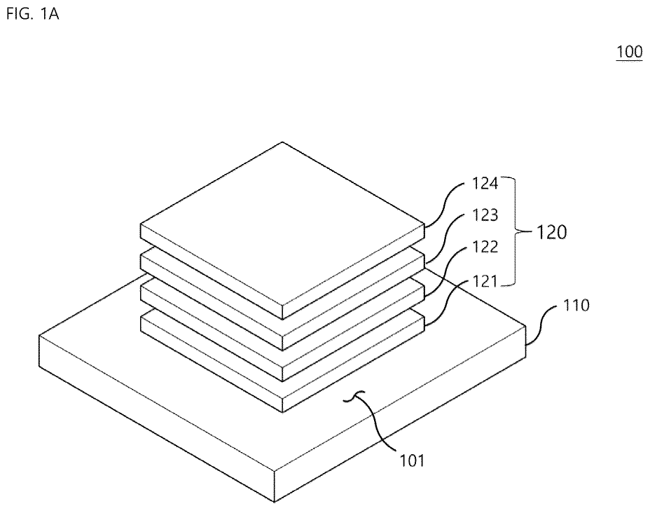

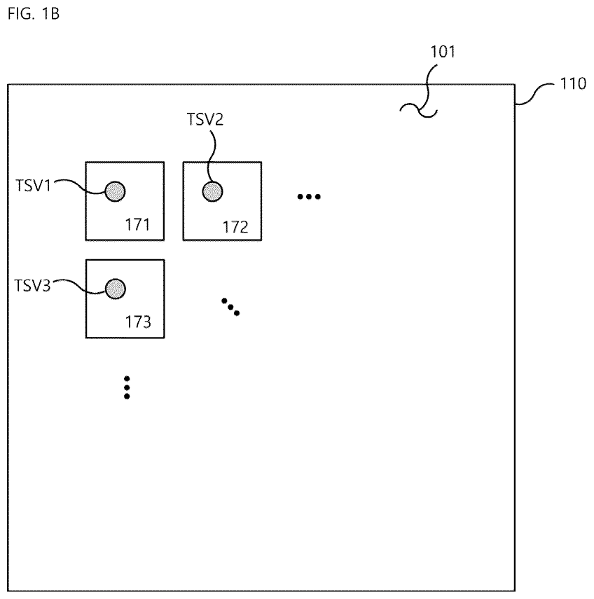

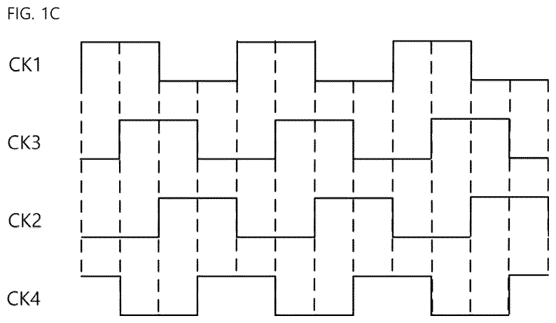

FIG. 1A is a perspective view illustrating a semiconductor device according to an example embodiment. FIG. 1B is a plan view illustrating a first surface of a logic die of FIG. 1A. FIG. 1C is a diagram illustrating a plurality of clock signals having different phases.

Referring to FIG. 1A, a semiconductor device 100 according to an example embodiment may include a logic die 110 and a memory device 120.

For example, a semiconductor device 100 may include a logic die 110 controlling the memory device 120.

The logic die 110 according to an example embodiment may write data to the memory device 120 or read data from the memory device 120. For example, the logic die 110 may input and output data to the memory device 120.

In addition, for example, the logic die 110 may execute applications, supported by the semiconductor device 100, using the memory device 120.

In addition, the semiconductor device 100 may include a memory device 120 disposed on a first surface 101 of the logic die 110.

For example, the semiconductor device 100 may include a memory device 120 disposed on the first surface 101 of the logic die 110 and connected to the logic die 110.

According to an example embodiment, the memory device 120 may include a plurality of memory dies 121, 122, 123, and 124 stacked on the first surface 101 of the logic die 110.

Therefore, the memory device 120 may be referred to as a high-bandwidth memory (HBM) including a plurality of memory dies 121, 122, 123, and 124 in a stacked configuration. In addition, each of the plurality of memory dies 121, 122, 123, and 124 may be referred to as an HBM DRAM device.

Furthermore, when the memory device 120 is referred to as an HBM, the semiconductor device 100 may be understood to have a three-dimensional HBM (3D HBM) structure in which the HBM is disposed on the first surface of the logic die 110.

Referring to FIGS. 1A and 1B, the semiconductor device 100 may include a plurality of through-silicon vias (TSVs) TSV1, TSV2, and TSV3.

For example, the semiconductor device 100 according to an example embodiment may include a plurality of TSVs TSV1, TSV2, and TSV3 connected to the logic die 110 through the first surface 101 of the logic die 110.

For example, the plurality of TSVs TSV1, TSV2, and TSV3 may be connected to the first surface 101 of the logic die 110 in the form of an array.

For example, the plurality of TSVs TSV1, TSV2, and TSV3 may be formed to penetrate at least a portion of the first surface 101 through the first surface 101.

In addition, the plurality of TSVs TSV1, TSV2, and TSV3 may be connected to the memory device 120 through a surface of the first memory die 121, adjacent to the first memory die 121. For example, the plurality of TSVs TSV1, TSV2, and TSV3 may be formed to penetrate through at least a portion of the plurality of memory dies 121, 122, 123, and 124.

For example, the logic die 110 and the memory device 120 may be connected through the plurality of TSVs TSV1, TSV2, and TSV3. For example, the logic die 110 and the memory device 120 may exchange data through the plurality of TSVs TSV1, TSV2, and TSV3.

For example, the logic die 110 may read data, stored in the memory device 120, from the memory device 120 through the plurality of TSVs TSV1, TSV2, and TSV3. In addition, for example, the logic die 110 may write data in the memory device 120 through the plurality of TSVs TSV1, TSV2, and TSV3.

Referring to FIG. 1B, the logic die 110 may include a plurality of integrated circuits 171, 172, and 173, respectively disposed adjacent to the plurality of TSVs TSV1, TSV2, and TSV3.

For example, the logic die 110 may include a plurality of integrated circuits 171, 172, and 173, respectively connected to the plurality of TSVs TSV1, TSV2, and TSV3.

For example, the logic die 110 may include a first integrated circuit 171 disposed adjacent to the first TSV TSV1 to be connected to the first TSV TSV1.

For example, the plurality of integrated circuits 171, 172, and 173 may be disposed in the form of an array.

According to an example embodiment, the plurality of integrated circuits 171, 172, and 173 may obtain data received through the plurality of TSVs TSV1, TSV2, and TSV3, respectively.

For example, the first integrated circuit 171 may obtain first input data transmitted from the memory device 120 through the first TSV TSV1 in a process of reading data from the memory device 120

According to an example embodiment, the plurality of integrated circuits 171, 172, and 173 may transmit data to the memory device 120 through the plurality of TSVs TSV1, TSV2, and TSV3, respectively.

For example, the second integrated circuit 172 may transmit the second input data to the memory device 120 through the second TSV TSV2 in a process of writing data in the memory device 120

For example, the plurality of integrated circuits 171, 172, and 173 may deserialize the data received through the plurality of TSVs TSV1, TSV2, and TSV3, respectively.

Data, transmitted from the memory device 120, may be transmitted in a double data rate (DDR) scheme.

Accordingly, the plurality of integrated circuits 171, 172, and 173 may deserialize the data received through the plurality of TSVs TSV1, TSV2, and TSV3 and output the parallel data in a single data rate (SDR) scheme.

Referring to FIGS. 1A and 1C, the memory device 120 may operate using a plurality of clock signals CK1, CK2, CK3, and CK4 having different phases.

For example, the memory device 120 may operate using at least a portion of the first clock signal CK1 to the fourth clock signal CK4 having a phase difference of 90 degrees.

For example, the memory device 120 may operate using the first clock signal CK1, the second clock signal CK2 having an anti-phase of the first clock signal CK1, the third clock signal CK3 having a phase difference of 90 degrees from the first clock signal CK1, and the fourth clock signal CK4 having an anti-phase of the third clock signal CK3.

According to an example embodiment, the logic die 110 may deserialize data transmitted from the memory device 120 using at least two clock signals, among the plurality of clock signals CK1, CK2, CK3, and CK4 used in the memory device 120.

For example, referring to FIGS. 1B and 1C, the first integrated circuit 171 may deserialize first input data, transmitted through the first TSV TSV1, using the first clock signal CK1 and the second clock signal CK2.

For example, the first integrated circuit 171 may generate first parallel data from the first input data, transmitted through the first TSV TSV1, using the first clock signal CK1. In addition, the first integrated circuit 171 may generate second parallel data from the first input data, transmitted through the first TSV TSV1, using the second clock signal CK2.

The first parallel data and the second parallel data may be output in an SDR scheme.

Referring to the above-described configurations, the logic die 110 according to an example embodiment may output data, received from the memory device 120 in the SDR scheme, using a rising edge of each of the plurality of clock signals CK1 and CK2 having different phases in the DDR scheme.

The above-described configurations may allow the semiconductor device 100 to reliably read data stored in the memory device 120, regardless of a duty of each clock signal. Thus, the logic die 110 may improve the performance of the semiconductor device 100.

In addition, the logic die 110 according to an example embodiment may output parallel data in a first-in first-out (FIFO) manner using one of the clock signals used to deserialize the data transmitted from the memory device 120.

For example, the logic die 110 may delay a single clock signal, among clock signals used to deserialize the data transmitted from the memory device 120, by a predetermined time.

Furthermore, the logic die 110 may capture and store (or hold) the parallel data in response to a rising edge of the delay clock signal.

For example, the first integrated circuit 171 may delay the second clock signal CK2 by a predetermined time.

Furthermore, the first integrated circuit 171 may capture and store the first parallel data and the second parallel data in response to the rising edge of the second clock signal CK2 delayed by the predetermined time.

Furthermore, the first integrated circuit 171 may output the stored data in a FIFO manner.

Referring to the above-described configurations, the logic die 110 according to an example embodiment may store two parallel data using a single rising edge of the clock signal delayed by the predetermined time.

As a result, the semiconductor device 100 may significantly reduce the number of cycles of the clock signal required to output data read from the memory device 120 in a FIFO manner.

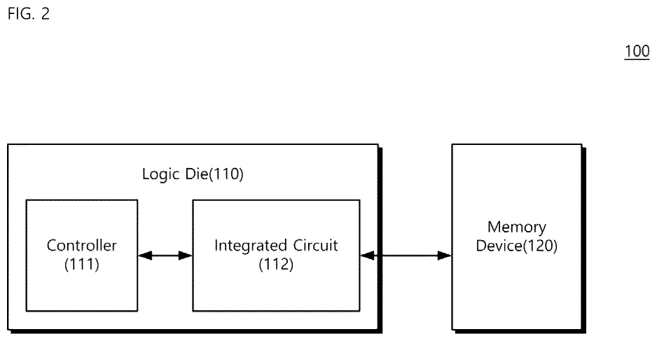

FIG. 2 is a block diagram illustrating a configuration of a semiconductor device according to an example embodiment.

Referring to FIG. 2, a semiconductor device 100 according to an example embodiment may include a logic die 110 and a memory device 120. In addition, the logic die 110 may include a controller 111 and an integrated circuit 112.

The semiconductor device 100 illustrated in FIG. 2 may be understood as an example of the semiconductor device 100 illustrated in FIG. 1A. In addition, the integrated circuit 112 illustrated in FIG. 2 may be understood to have substantially the same configuration as the first integrated circuit 171 illustrated in FIG. 1B.

Therefore, the same or substantially the same components are denoted by the same or substantially the same reference numerals, and redundant descriptions are omitted to avoid repetition.

The logic die 110 may include a controller 111 controlling an operation of the logic die 110.

The controller 111 may execute software (or programs) to control at least a portion of one or more other components (for example, the integrated circuit 112) of the logic die 110 and perform various data processing or operations. In addition, the controller 111 may include a central processing unit, a microprocessor, or the like, and may control the overall operation of the logic die 110. Therefore, an operation performed by the logic die 110 may be understood to be performed under the control of the controller 111.

The controller 111 may write data in the memory device 120 or read data stored in the memory device 120.

For example, the controller 111 may transmit a read command to the memory device 120 to read data stored in the memory device 120. Furthermore, the controller 111 may obtain data, output in response to the read command, from the memory device 120.

In addition, the controller 111 may transmit data and a write command to the memory device 120 to write the data in the memory device 120.

In addition, the logic die 110 may include an integrated circuit 112 exchanging data with the memory device 120.

For example, the integrated circuit 112 may transmit the read command, output from the controller 111, to the memory device 120.

In addition, the integrated circuit 112 may obtain data, output in response to the read command, from the memory device 120. The integrated circuit 112 may transmit the data, obtained from the memory device 120, to the controller 111.

For example, data output from the memory device 120 in response to the read command may be transmitted to the integrated circuit 112 through at least portion of the TSVs.

In addition, the integrated circuit 112 may transmit the write command and data, transmitted from the controller 111, to the memory device 120.

For example, the integrated circuit 112 may include a double data rate physical layer (DDR PHY). In addition, the integrated circuit 112 may communicate with the controller 111 and/or the memory device 120 with a DDR PHY interface (DPI).

In addition, for example, the integrated circuit 112 may support features of the DDR and/or low-power DDR (LPDDR) protocols of the Joint Electron Device Engineering Council (JEDEC) standard.

According to an example embodiment, the integrated circuit 112 may deserialize data received from the memory device 120. The data, transmitted from the memory device 120, may be transmitted in a DDR scheme.

Accordingly, the integrated circuit 112 may deserialize the data received from the memory device 120 and output the parallel data in an SDR scheme.

According to an example embodiment, the integrated circuit 112 may deserialize data, received from the memory device 120, using at least two clock signals, among the plurality of clock signals CK1, CK2, CK3, and CK4 used in the memory device 120.

For example, the integrated circuit 112 may generate first parallel data from first input data, transmitted from the memory device 120, using the first clock signal CK1. In addition, the first integrated circuit 171 may generate second parallel data from the first input data using the second clock signal CK2.

The first parallel data and the second parallel data may be output in an SDR scheme.

Referring to the above-described configurations, the integrated circuit 112 according to an example embodiment may output data received from the memory device 120 in an SDR scheme using a rising edge of each of the plurality of clock signals CK1 and CK2 having different phases.

The above-described configurations may allow the semiconductor device 100 to reliably read data stored in the memory device 120, regardless of a duty of each clock signal.

In addition, the integrated circuit 112 according to an example embodiment may output the parallel data in a first-in first-out (FIFO) manner using one of the clock signals used to deserialize the data transmitted from the memory device 120.

For example, the integrated circuit 112 may delay one of the clock signals, used to deserialize the data transmitted from the memory device 120, by a predetermined time.

Furthermore, the integrated circuit 112 may capture and store (or hold) the parallel data in response to a rising edge of the delay clock signal.

For example, the integrated circuit 112 may delay the second clock signal CK2 by a predetermined time.

Furthermore, the integrated circuit 112 may capture and store the first parallel data and the second parallel data in response to the rising edge of the second clock signal CK2 delayed by the predetermined period.

Furthermore, the integrated circuit 112 may output the stored data in a FIFO manner.

Referring to the above-described configurations, the integrated circuit 112 according to an example embodiment may store two parallel data using a single rising edge of a clock signal delayed for a predetermined time.

As a result, the semiconductor device 100 may significantly reduce the number of cycles of the clock signal required to output data read from the memory device 120 in a FIFO manner.

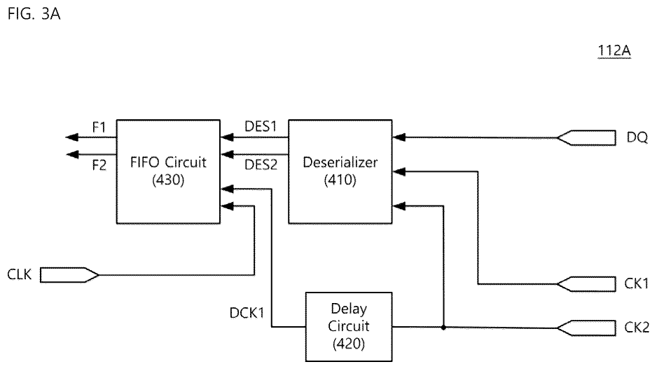

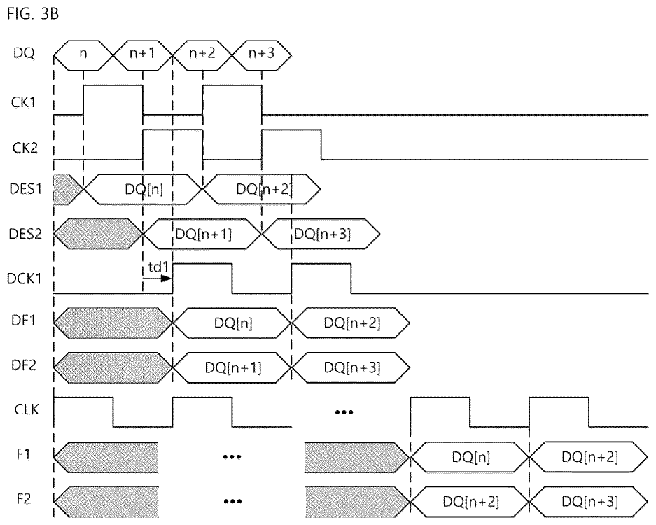

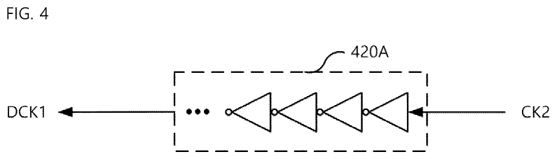

FIG. 3A is a circuit diagram illustrating an integrated circuit reading data according to an example embodiment, and FIG. 3B is a diagram illustrating data output through the integrated circuit of FIG. 3A. FIG. 4 is a circuit diagram illustrating a configuration of a delay circuit of FIG. 3A.

Referring to FIG. 3A, the integrated circuit 112A according to an example embodiment may include a deserializer 410, a delay circuit 420, and a FIFO circuit 430.

The integrated circuit 112A illustrated in FIG. 3A may be understood as an example of the integrated circuit 112 illustrated in FIG. 2.

According to an example embodiment, the integrated circuit 112A may include a deserializer 410 obtaining input data DQ from the memory device 120.

In here, the deserializer 410 may be referred to as a circuit that converts input serial data into parallel data and outputs it. For example, the deserializer 410 may include at least one flip-flop that outputs data in response to a clock signal.

For example, the deserializer 410 may deserialize the input data DQ using a first clock signal CK1 and a second clock signal CK2. The first clock signal CK1 and the second clock signal CK2 may have a phase difference of 180 degrees.

Referring to FIGS. 3A and 3B, the deserializer 410 may output first parallel data DES1 from the input data DQ using the first clock signal CK1.

For example, the deserializer 410 may output first parallel data DES1 including “DQ[n]” and “DQ[n+2]” corresponding to a rising edge of the first clock signal CK1, among bits of the input data DQ.

For example, the deserializer 410 may output first parallel data DES1 including odd bits, among the bits of the input data DQ, using the first clock signal CK1.

In addition, the deserializer 410 may output second parallel data DES2 from the input data DQ using the second clock signal CK2.

For example, the deserializer 410 may output second parallel data DES2 including “DQ[n+1]” and “DQ[n+3]” corresponding to a rising edge of the second clock signal CK2, among the bits of the input data DQ.

For example, the deserializer 410 may output second parallel data DES2 including even bits, among the bits of the input data DQ, using the second clock signal CK2.

Referring to the above-described configurations, the deserializer 410 according to an example embodiment may deserialize the input data DQ using the rising edge of each of the clock signals CK1 and CK2 having different phases.

As a result, the integrated circuit 112A according to an example embodiment may reliably read data transmitted from the memory device 120, regardless of a duty of each of the clock signals CK1 and CK2.

In addition, the integrated circuit 112A may include a delay circuit 420 delaying the second clock signal CK2 by a first delay time td1.

For example, the delay circuit 420 may delay the phase of the second clock signal CK2 by the first delay time td1 to output a first delay clock signal DCK1.

Referring to FIG. 4, a delay circuit 420A according to an example embodiment may include an even number of inverters connected in series. The delay circuit 420A may be understood as an example of the delay circuit 420 illustrated in FIG. 3A.

The delay circuit 420A may delay a phase of a second clock signal CK2 in proportion to the number of paired inverters.

According to an example embodiment, the delay circuit 420 may include a plurality of buffers connected in series.

The delay circuit 420 may delay a phase of the second clock signal CK2 in proportion to the number of buffers.

However, the configuration of the delay circuit 420 is not limited to the above-described examples, and the delay circuit 420 may have various configurations to delay the phase of the second clock signal CK2 by the first delay time td1.

In addition, the integrated circuit 112A may include a FIFO circuit 430 processing first parallel data DES1 and second parallel data DES2 in a FIFO manner. In here, the FIFO circuit 430 may be referred to as a circuit that outputs data according to the order of input data in a first-in, first out manner in response to a clock signal.

For example, the FIFO circuit 430 may sample the first parallel data DES1 and the second parallel data DES2 using the second clock signal CK2.

According to an example embodiment, the FIFO circuit 430 may sampling the first parallel data DES1 and the second parallel data DES2 using the first delay clock signal DCK1 generated based on the second clock signal CK2.

According to an example embodiment, the FIFO circuit 430 may capture and hold the first parallel data DES1 and the second parallel data DES2 using a rising edge of the first delay clock signal DCK1.

Referring to FIGS. 3A and 3B, the FIFO circuit 430 according to an example embodiment may capture “DQ[n]” of the first parallel data DES1 and “DQ[n+1]” of the second parallel data DES2 in response to the rising edge of the first delay clock signal DCK1.

In addition, the FIFO circuit 430 may capture “DQ[n+2]” of the first parallel data DES1 and “DQ[n+3]” of the second parallel data DES2 in response to the rising edge of the first delay clock signal DCK1.

For example, referring to the above-described configurations, the FIFO circuit 430 may capture the first parallel data DES1 and the second parallel data DES2 together in response to one rising edge of the first delay clock signal DCK1.

As a result, the integrated circuit 112A may significantly reduce the number of cycles of a clock signal required to process data read from the memory device 120 in a FIFO manner.

Referring to the above-described configurations, the integrated circuit 112A according to an example embodiment may capture the first parallel data DES1 and the second parallel data DES2 using the first delay clock signal DCK1 generated by delaying the second clock signal CK2 by the first delay time td1.

Thus, the two parallel data DES1 and DES2 may be captured with a relatively small amount of delay time, compared to the case in which the two parallel data DES1 and DES2 are captured using a signal generated by delaying the first clock signal CK1.

For example, the integrated circuit 112A may capture the two parallel data DES1 and DES2 using the first delay clock signal DCK1, generated by delaying the second clock signal CK2, to significantly reduce a delay time caused by the delay circuit 420.

As a result, the integrated circuit 112A according to an example embodiment may significantly reduce power consumed by the delay circuit 420. In addition, the integrated circuit 112A may significantly reduce an area of the delay circuit 420.

According to one or more embodiments, among the components of the integrated circuit 112, the delay circuit 420 may be omitted.

For example, the FIFO circuit 430 according to an example embodiment may capture (or store) the first parallel data DES1 and the second parallel data DES2 in response to the second clock signal CK2.

For example, the FIFO circuit 430 may capture “DQ[n]” of the first parallel data DES1 and “DQ[n+1]” of the second parallel data DES2 in response to the rising edge of the second clock signal CK2.

In addition, the FIFO circuit 430 may capture “DQ[n+2]” of the first parallel data DES1 and “DQ[n+3]” of the second parallel data DES2 in response to the rising edge of the second clock signal CK2.

Furthermore, the FIFO circuit 430 may store a results of sampling the first parallel data DES1 and the second parallel data DES2.

For example, the FIFO circuit 430 may store the first sampling data DF1 as a result of sampling the first parallel data DES1. In addition, the FIFO circuit 430 may store the second sampling data DF2 as a result of sampling the second parallel data DES2.

In addition, the FIFO circuit 430 may output the stored data in a FIFO manner.

For example, the FIFO circuit 430 may output first sampling data DF1 and second sampling data DF2 in response to the memory clock signal CLK.

For example, the memory clock signal CLK may be understood as a clock signal controlling an operation of a controller (for example, the controller 111 of FIG. 2) of a logic die (for example, the logic die 110 of FIG. 2).

For example, the FIFO circuit 430 may output the first sampling data DF1 and the second sampling data DF2 in response to the rising edge of the memory clock signal CLK.

Referring to FIG. 3B, the FIFO circuit 430 may output the first sampling data DF1 as first output data F1 in response to the rising edge of the memory clock signal CLK.

In addition, the FIFO circuit 430 may output the second sampling data DF2 as second output data F2 in response to the rising edge of the memory clock signal CLK.

Each of the first output data F1 and the second output data F2 may be output in an SDR scheme.

For example, the integrated circuit 112A may convert the input data DQ, read from the memory device 120 in a DDR scheme, in an SDR scheme and output the converted data using the plurality of clock signals CK1 and CK2 having different phases (for example, an anti-phase).

As a result, the integrated circuit 112A according to an example embodiment may output data transmitted from the memory device 120 in the SDR scheme, regardless of a duty of each of the clock signals CK1 and CK2.

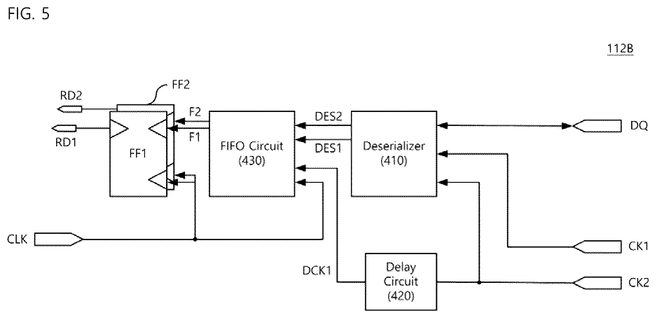

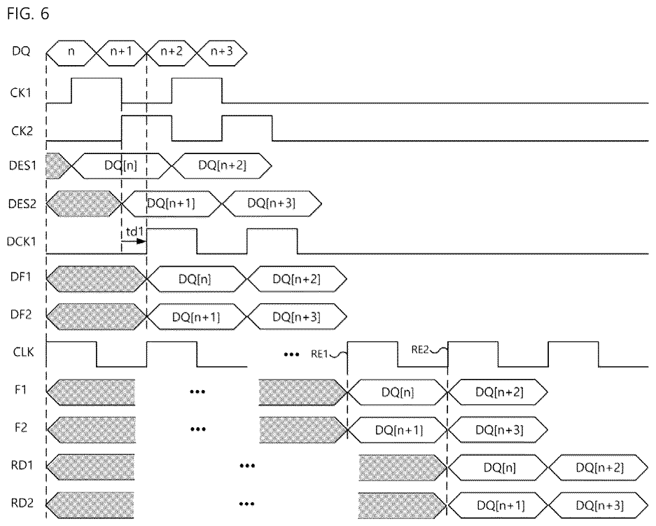

FIG. 5 is a circuit diagram illustrating an integrated circuit reading data according to an example embodiment. FIG. 6 is a diagram illustrating data output through the integrated circuit of FIG. 5.

Referring to FIG. 5, the integrated circuit 112B according to an example embodiment may include a deserializer 410, a delay circuit 420, a FIFO circuit 430, a first flip-flop FF1, and a second flip-flop FF2.

The integrated circuit 112B illustrated in FIG. 5 may be understood as an example of the integrated circuit 112 illustrated in FIG. 2.

In addition, the integrated circuit 112B of FIG. 5 may be understood as an example that further includes a first flip-flop FF1 and a second flip-flop FF2, in addition to the configuration of the integrated circuit 112A illustrated in FIG. 3A.

Therefore, the same or substantially the same components are denoted by the same or substantially the same reference numerals, and redundant descriptions are omitted to avoid repetition.

According to an example embodiment, the integrated circuit 112B may include a first flip-flop FF1 and a second flip-flop FF2 that output the data output from the FIFO circuit 430.

For example, each of the first flip-flop FF1 and the second flip-flop FF2 may output data transmitted from the FIFO circuit 430 in response to a memory clock signal CLK.

Referring to FIG. 6, the first flip-flop FF1 may output first output data F1 as first read data RD1 in response to the memory clock signal CLK.

For example, the first flip-flop FF1 may output the first output data F1, output from the FIFO circuit 430, as the first read data RD1 in response to a rising edge of the memory clock signal CLK.

The second flip-flop FF2 may output second output data F2 as second read data RD2 in response to the memory clock signal CLK.

For example, the second flip-flop FF2 may output the second output data F2, output from the FIFO circuit 430, as second read data RD2 in response to the rising edge of the memory clock signal CLK.

For example, the FIFO circuit 430 may output the first output data F1 and the second output data F2 in response to a first rising edge RE1 of the memory clock signal CLK.

Furthermore, the first flip-flop FF1 may output the first output data F1 as the first read data RD1 in response to a second rising edge RE2, subsequent to the first rising edge RE1 of the memory clock signal CLK.

The second flip-flop FF2 may output the second output data F2 as the second read data RD2 in response to the second rising edge RE2 of the memory clock signal CLK.

Each of the first flip-flop FF1 and the second flip-flop FF2 may output the first read data RD1 and the second read data RD2 to a controller (for example, the controller 111 of FIG. 2).

Each of the first read data RD1 and the second read data RD2 may be output in an SDR scheme.

For example, the integrated circuit 112B may convert input data DQ, read from the memory device 120 in a DDR scheme, in an SDR scheme and output the converted data using rising edges of a plurality of clock signals CK1 and CK2 having different phases (for example, an anti-phase).

As a result, the integrated circuit 112B according to an example embodiment may reliably read data output from the memory device 120, regardless of a duty of each of the clock signals CK1 and CK2.

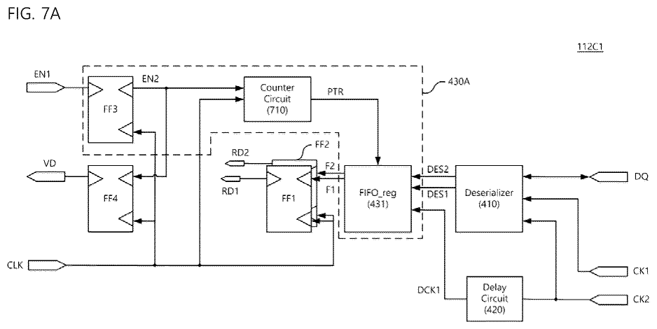

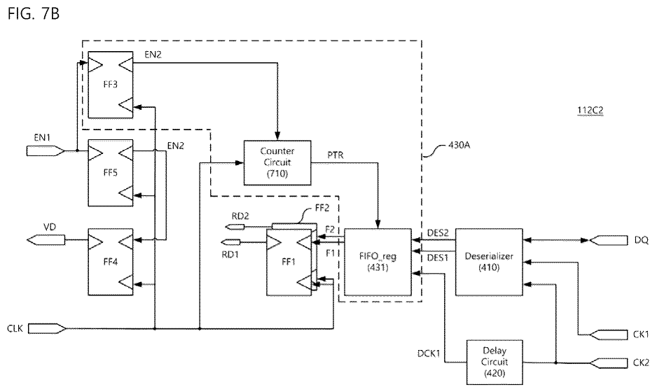

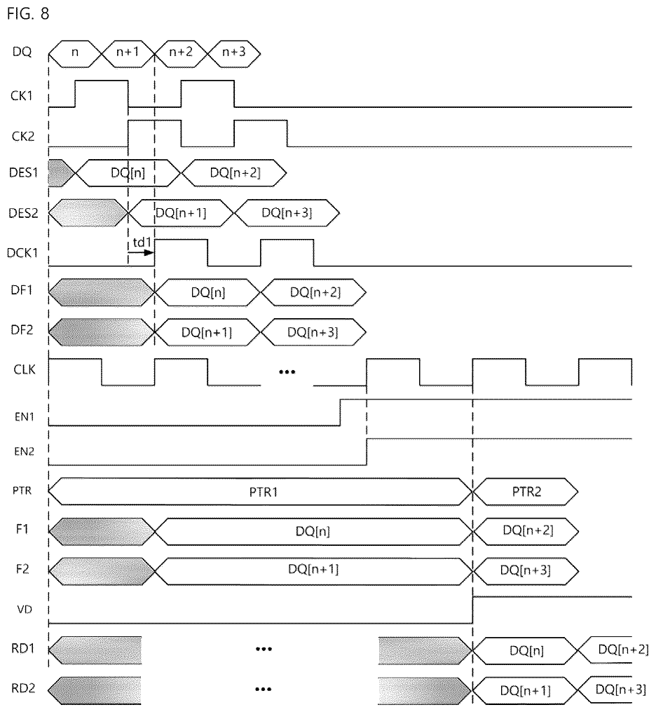

FIG. 7A is a circuit diagram illustrating an integrated circuit reading data according to an example embodiment, and FIG. 7B is a circuit diagram illustrating an integrated circuit further including a fifth flip-flop in the configuration of FIG. 7A. FIG. 8 is a diagram illustrating data output through the integrated circuit of FIG. 7A.

Referring to FIG. 7A, the integrated circuit 112C1 according to an example embodiment may include a deserializer 410, a delay circuit 420, and a FIFO circuit 430A. The FIFO circuit 430A may include a third flip-flop FF3, a counter circuit 710, and a FIFO register (FIFO_reg) 431.

The integrated circuit 112C1 illustrated in FIG. 7A may be understood as an example of the integrated circuit 112 illustrated in FIG. 2. In addition, the FIFO circuit 430A illustrated in FIG. 7A may be understood as an example of the FIFO circuit 430 illustrated in FIG. 5.

In addition, the integrated circuit 112C1 illustrated in FIG. 7A may be understood as an example that further includes a fourth flip-flop FF4, in addition to the configuration of the integrated circuit 112B illustrated in FIG. 5.

Therefore, the same or substantially the same components are denoted by the same or substantially the same reference numerals, and redundant descriptions are omitted to avoid repetition.

According to an example embodiment, the FIFO circuit 430A may include a third flip-flop FF3 receiving a first enable signal EN1.

For example, the third flip-flop FF3 may receive the first enable signal EN1 from a controller (for example, the controller 111 of FIG. 2).

In addition, the third flip-flop FF3 may output a second enable signal EN2 in response to the memory clock signal CLK.

For example, the third flip-flop FF3 may output a second enable signal EN2 from the first enable signal EN1 in response to a rising edge of the memory clock signal CLK.

For example, the third flip-flop FF3 may output the first enable signal EN1, delayed by ¼ of a cycle of the memory clock signal CLK, as a second enable signal EN2.

Referring to FIG. 7B according to an example embodiment, an integrated circuit 112C2 may further include a fifth flip-flop FF5 receiving a first enable signal EN1.

For example, the fifth flip-flop FF5 may receive the first enable signal EN1 from a controller (for example, the controller 111 of FIG. 2).

In addition, the fifth flip-flop FF5 may output a second enable signal EN2 in response to the memory clock signal CLK.

For example, the fifth flip-flop FF5 may output the second enable signal EN2 from the first enable signal EN1 in response to a rising edge of the memory clock signal CLK.

For example, the fifth flip-flop FF5 may output the first enable signal EN1, delayed by ¼ of a cycle of the memory clock signal CLK, as the second enable signal EN2. Referring to FIGS. 7A and 7B, the FIFO circuit 430A according to an example embodiment may include a counter circuit 710 obtaining the second enable signal EN2.

That is, in here, the counter circuit 710 may be referred to as a circuit that counts and outputs the number of times a rising edge of an input clock signal occurs over a certain period of time.

For example, the counter circuit 710 may count the number of rising edges of the memory clock signal CLK while the second enable signal EN2 is maintained at a logic high level.

The counter circuit 710 may output a pointer signal PTR according to the rising edge of the memory clock signal CLK while the second enable signal EN2 is maintained at a logic high level.

For example, referring to FIG. 8, the counter circuit 710 may output a first pointer signal PTR1 until a first rising edge of the memory clock signal CLK occurs after the second enable signal EN2 transitions to a logic high level.

In addition, the counter circuit 710 may output a second pointer signal PTR2 in response to the first rising edge of the memory clock signal CLK occurring while the second enable signal EN2 is maintained at a logic high level.

According to an example embodiment, the FIFO circuit 430A may include a FIFO register 431 outputting first output data F1 and second output data F2.

According to an example embodiment, the FIFO register 431 may sample (or store) first parallel data DES1 and second parallel data DES2 in response to a first delay clock signal DCK1.

For example, the FIFO register 431 may sample the first parallel data DES1 in response to a rising edge of the first delay clock signal DCK1 and store the sampled data as first sampling data DF1.

In addition, the FIFO register 431 may sample the second parallel data DES2 in response to the rising edge of the first delay clock signal DCK1 and store the sampled data as second sampling data DF2.

Furthermore, the FIFO register 431 may output the first output data F1 and the second output data F2 based on the pointer signal PTR transmitted from the counter circuit 710.

For example, the FIFO register 431 may output data, corresponding to the pointer signal PTR transmitted from the counter circuit 710, from data stored in the FIFO register 431.

For example, the FIFO register 431 may output a data bit “DQ[n]” corresponding to the first pointer signal PTR1, among bits of the first sampling data DF1, as the first output data F1 in response to the first pointer signal PTR1.

In addition, the FIFO register 431 may output a data bit “DQ[n+1]” corresponding to the first pointer signal PTR1, among bits of the second sampling data DF2, as the second output data F2 in response to the first pointer signal PTR1.

For example, the FIFO register 431 may output a data bit “DQ[n+2]” corresponding to the second pointer signal PTR2, among the bits of the first sampling data DF1, as the first output data F1 in response to the second pointer signal PTR2.

In addition, the FIFO register 431 may output a data bit “DQ[n+3]” corresponding to the second pointer signal PTR2, among the bits of the second sampling data DF2, as the second output data F2 in response to the second pointer signal PTR2.

The integrated circuits 112C1 and 112C2 according to an example embodiment may include a fourth flip-flop FF4 outputting a valid signal VD based on the second enable signal EN2.

For example, the fourth flip-flop FF4 may obtain the second enable signal EN2 output from the third flip-flop FF3 or the fifth flip-flop FF5.

Referring to FIG. 8, the fourth flip-flop FF4 may output a valid signal VD having a logic high level in response to the rising edge of the memory clock signal CLK.

For example, the fourth flip-flop FF4 may output a high-level valid signal VD to the controller 111 in response to the rising edge of the memory clock signal CLK.

The controller 111 may obtain the first read data RD1 and the second read data RD2 output from the first flip-flop FF1 in response to the high-level valid signal VD being received.

For example, the controller 111 may identify the first read data RD1 and the second read data RD2 as data that has been validly read from the memory device 120, in response to the high-level valid signal VD being received.

For example, the controller 111 may identify (or obtain) data output while the valid signal VD is maintained at a logic high level, among data output from the first flip-flop FF1, as data that has been validly read from the memory device 120.

Referring to the above-described configurations, the integrated circuits 112C1 and 112C2 according to an example embodiment may transmit the first read data RD1 and the second read data RD2 to the controller 111 based on the first enable signal EN1 received from the controller 111.

The controller 111 may identify (or obtain) the data, transmitted while the valid signal VD is maintained at a logic high level, as the data that has been validly read from the memory device 120.

As a result, the semiconductor device 100 according to an example embodiment may significantly reduce power consumption for reading data from the memory device 120.

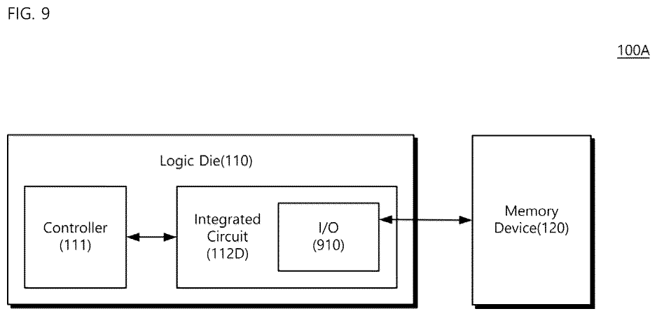

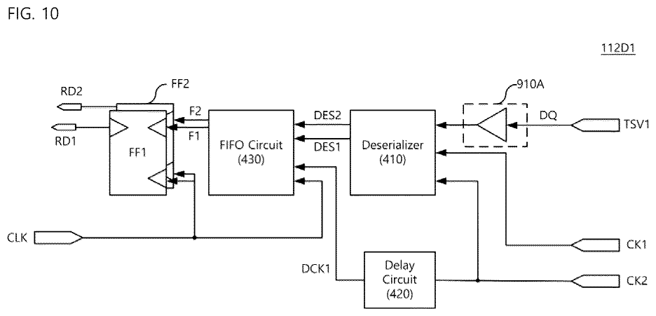

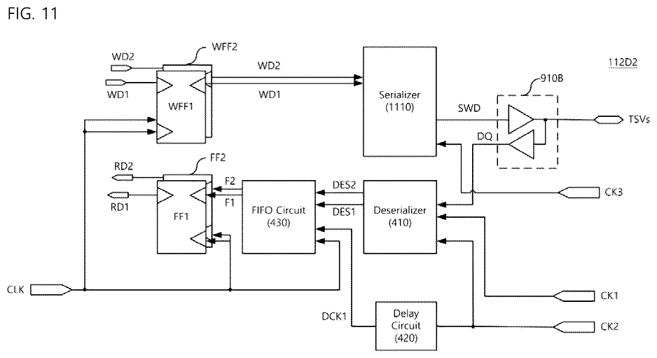

FIG. 9 is a circuit diagram illustrating a semiconductor device according to an example embodiment. FIG. 10 is a circuit diagram illustrating an integrated circuit including an input/output circuit obtaining data read from a memory device according to an example embodiment. FIG. 11 is a circuit diagram illustrating an integrated circuit including an input/output circuit exchanging data with a memory device according to an example embodiment.

Referring to FIG. 9, a semiconductor device 100A according to an example embodiment may include a logic die 110 and a memory device 120. The logic die 110 may include a controller 111 and an integrated circuit 112D.

The integrated circuit 112D according to an example embodiment may further include an input/output circuit 910 exchanging data with the memory device 120.

The semiconductor device 100A illustrated in FIG. 9 may be understood as an example of the semiconductor device 100 illustrated in FIG. 2. In addition, the semiconductor device 100A illustrated in FIG. 9 may be understood as an example that further includes an input/output circuit 910, in addition to the configuration of the semiconductor device 100 illustrated in FIG. 2.

Therefore, the same or substantially the same components are denoted by the same or substantially the same reference numerals, and redundant descriptions are omitted to avoid repetition.

According to an example embodiment, the controller 111 may exchange data with the memory device 120 through the input/output circuit 910 included in the integrated circuit 112D.

In here, the input/output circuit 910 may be referred to as a circuit that controls data exchange between the logic die 110 and the memory device 120.

For example, the controller 111 may obtain data, transmitted from the memory device 120 through a plurality of TSVs, using the input/output circuit 910.

In addition, the controller 111 may transmit data to be written in the memory device 120 to the memory device 120 through a plurality of TSVs using the input/output circuit 910.

For example, the input/output circuit 910 according to an example embodiment may exchange data with the memory device 120 through a plurality of TSVs connecting the logic die 110 and the memory device 120.

According to an example embodiment, the logic die 110 and the memory device 120 may be connected through a plurality of through back-end-of-line (BEOL) vias (TBVs).

Accordingly, the input/output circuit 910 may exchange data with the memory device 120 through a plurality of TBVs connecting the logic die 110 and the memory device 120.

According to an example embodiment, the input/output circuit 910 may include a DDR physical layer (DDR PHY). The input/output circuit 910 may communicate with the controller 111 and/or the memory device 120 with a DDR PHY interface (DFI).

Referring to FIG. 10, the integrated circuit 112D1 according to an example embodiment may include a deserializer 410, a delay circuit 420, a FIFO circuit 430, a first flip-flop FF1, a second flip-flop FF2, and an input/output circuit 910A.

The integrated circuit 112D1 may include an input/output circuit 910A obtaining input data DQ received from the memory device 120 through a first TSV TSV1.

The input/output circuit 910A illustrated in FIG. 10 may be understood as an example of the input/output circuit 910 illustrated in FIG. 9. In addition, the integrated circuit 112D1 may be understood as an example that further includes an input/output circuit 910A, in addition to the configuration of the integrated circuit 112B illustrated in FIG. 5.

Therefore, the same or substantially the same components are denoted by the same or substantially the same reference numerals, and redundant descriptions are omitted to avoid repetition.

According to an example embodiment, the input/output circuit 910A may obtain input data DQ transmitted from the memory device 120 through the first TSV TSV1.

In addition, the controller 111 according to an example embodiment may control the input/output circuit 910A to control a voltage level of a signal received through the first TSV TSV1.

For example, when the memory device 120 and the logic die 110 operate using different levels of operating voltage, the controller 111 may control the voltage level of the signal obtained through the first TSV TSV1 to correspond to the level of the operating voltage of the logic die 110, using the input/output circuit 910A.

Referring to FIG. 11, an integrated circuit 112D2 according to an example embodiment may include a deserializer 410, a delay circuit 420, a FIFO circuit 430, a first flip-flop FF1, a second flip-flop FF2, an input/output circuit 910B, a serializer 1110, a first write flip-flop WFF1, and a second write flip-flop WFF2.

The integrated circuit 112D2 may include an input/output circuit 910B exchanging data with the memory device 120 through a plurality of through-silicon vias (TSVs).

The plurality of TSVs may be understood as having substantially the same configuration as the plurality of TSVs TSV1, TSV2, and TSV3 illustrated in FIG. 1b.

In addition, the input/output circuit 910B may be understood as an example of the input/output circuit 910 illustrated in FIG. 9.

The integrated circuit 112D2 illustrated in FIG. 11 may be understood as an example that further includes an input/output circuit 910B, a serializer 1110, a first write flip-flop WFF1, and a second write flip-flop WFF2, in addition to the configuration of the integrated circuit 112B illustrated in FIG. 5.

Therefore, the same or substantially the same components are denoted by the same or substantially the same reference numerals, and redundant descriptions are omitted to avoid repetition.

According to an example embodiment, the input/output circuit 910B may obtain input data DQ transmitted from a memory device 120 through a first TSV TSV1.

In addition, the input/output circuit 910B may transmit serial write data SWD to the memory device 120 through a second TSV TSV2.

The integrated circuit 112D2 according to an example embodiment may further include a first write flip-flop WFF1 and a second write flip-flop WFF2, respectively obtaining first write data WD1 and second write data WD2 from the controller 111.

For example, the first write flip-flop WFF1 may output the first write data WD1, obtained from the controller 111, in response to the memory clock signal CLK.

In addition, the second write flip-flop WFF2 may output the second write data WD2, obtained from the controller 111, in response to the memory clock signal CLK.

In addition, the integrated circuit 112D2 may include a serializer 1110 serializing the first write data WD1 and the second write data WD2.

In here, a serializer 1110 may be referred to as a circuit that converts input parallel data into serial data and outputs it. For example, the serializer 1110 may include a plurality of flip-flops that are connected to each other.

For example, the serializer 1110 may serialize the first write data WD1 and the second write data WD2 using a third clock signal CK3.

For example, the serializer 1110 may output serial write data SWD, consisting of bits of the first write data WD1 and the second write data WD2, in response to a rising edge of the third clock signal CK3.

Furthermore, the input/output circuit 910B may transmit the serial write data SWD to the memory device 120 through a first TSV TSV1.

Referring to the above-described configurations, the semiconductor device 100A according to an example embodiment may read data stored in the memory device 120 or store data in the memory device 120 through the integrated circuit 112D.

The integrated circuit 112D may output the input data DQ, transmitted from the memory device 120, as first read data RD1 and second read data RD2 using rising edges of the clock signals CK1 and CK2 having different phases.

For example, the integrated circuit 112D may output the input data DQ, received from the memory device 120 in a DDR scheme, in an SDR scheme using the rising edge of each of the clock signals CK1 and CK2 having different phases.

As a result, the semiconductor device 100A may reliably read data stored in the memory device 120 regardless of a duty of each clock signal.

As described above, the integrated circuit 112 according to an example embodiment may output data, received from the memory device 120 in the DDR scheme, in the SDR scheme using the rising edge of each of the plurality of clock signals CK1 and CK2 having different phases.

As a result, the semiconductor device 100 may reliably read data stored in the memory device 120 regardless of a duty of each clock signal.

In addition, referring to the above-described configurations, the integrated circuit 112 according to an example embodiment may store two parallel data using a single rising edge of a clock signals delayed by a predetermined time.

As a result, the semiconductor device 100 may significantly reduce the number of cycles of a clock signal required to output data read from the memory device 120 in a first-in first-out (FIFO) manner.

In addition, referring to the above-described configurations, the integrated circuit 112 according to an example embodiment may capture first parallel data DES1 and second parallel data DES2 using the first delay clock signal DCK1 generated by delaying the second clock signal CK2 by a first delay time td1.

The two parallel data DES1 and DES2 may be captured with a relatively small amount of delay time, compared to the case in which the two deserialized data DES1 and DES2 are captured using a signal generated by delaying the first clock signal CK1.

For example, the integrated circuit 112 may capture the two parallel data DES1 and DES2 using the first delay clock signal DCK1, generated by delaying the second clock signal CK2, to significantly reduce a delay time caused by the delay circuit.

As a result, the integrated circuit 112 according to the example embodiment may significantly reduce power consumption caused by the delay circuit 420. In addition, the integrated circuit 112 may significantly reduce an area of the delay circuit 420.

As set forth above, a semiconductor device according to example embodiments may stably read data, regardless of a duty of each clock signal, using clock signals having different phases.

At least one of the components, elements, modules, units, or the like (collectively “components” in this paragraph) represented by a block or an equivalent indication (collectively “block”) in the above embodiments including the drawings such as FIGS. 2, 3A, 5, 7A, 7B, 9, 10 and 11, for example, deserializer, serializer, FIFO circuit, delay circuit, controller, counter circuit, flip-flop, latch, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

While example embodiments have been shown and described above, it will be apparent to those skilled in the art that modifications and variations could be made without departing from the scope of the present disclosure as defined by the appended claims.

What is claimed is:

1. A semiconductor device comprising:
a logic die; and
a memory device connected to the logic die,
wherein the logic die comprises:
a deserializer configured to output first parallel data based on input data received from the memory device using a first clock signal having a first phase and output second parallel data based on the input data using a second clock signal having a second phase, wherein the first phase is different from the second phase; and
a first-in first-out (FIFO) circuit configured to:
sample the first parallel data using the second clock signal and store the sampled first parallel data as first sampling data,
sample the second parallel data using the second clock signal and store the sampled second parallel data as second sampling data,
output the first sampling data as first output data in response to a rising edge of a memory clock signal, and
output the second sampling data as second output data in response to the rising edge of the memory clock signal.

2. The semiconductor device of claim 1,
wherein the logic die further comprises a first flip-flop and a second flip-flop,
wherein the first and the second flip-flops are connected to the FIFO circuit,
wherein the first flip-flop is configured to output the first output data as first read data in response to the memory clock signal, and
wherein the second flip-flop is configured to output the second output data as second read data in response to the memory clock signal.

3. The semiconductor device of claim 2,
wherein the logic die further comprises:
a controller configured to execute one or more instructions which cause the controller to extract data from the memory device;
a third flip-flop configured to output a second enable signal based on a first enable signal, received from the controller, in response to the memory clock signal; and
a counter circuit configured to output a pointer signal in response to the rising edge of the memory clock signal while the second enable signal is maintained at a logic high level, and
wherein the FIFO circuit is further configured to output data corresponding to the pointer signal transmitted from the counter circuit.

4. The semiconductor device of claim 3,
wherein the counter circuit is further configured to output a first pointer signal in response to a first rising edge of the memory clock signal while the second enable signal is maintained at a logic high level, and
wherein the FIFO circuit is further configured to:
output a data bit corresponding to the first pointer signal, among bits of the first sampling data, as the first output data; and
output a data bit corresponding to the first pointer signal, among bits of the second sampling data, as the second output data.

5. The semiconductor device of claim 3,
wherein the logic die further comprises a fourth flip-flop configured to output a valid signal based on the second enable signal in response to the rising edge of the memory clock signal, and
wherein the controller is further configured to execute the one or more instructions which cause the controller to, based on the valid signal being logic high, obtain the first read data and the second read data.

6. The semiconductor device of claim 3,
wherein the input data is received in a double data rate (DDR) scheme, and
wherein the controller is further configured to execute the one or more instructions which cause the controller to read the first read data and the second read data in a single data rate (SDR) scheme.

7. The semiconductor device of claim 3,
wherein the memory device comprises a plurality of memory dies stacked on one surface of the logic die, and
wherein the plurality of memory dies are configured to exchange data with the logic die through a plurality of through-silicon vias (TSVs).

8. The semiconductor device of claim 7,
wherein the logic die further comprises an input/output circuit configured to receive the input data through a first TSV, and
wherein the controller is further configured to execute the one or more instructions which cause the controller to control a voltage level of a signal received through the first TSV, using the input/output circuit.

9. The semiconductor device of claim 1,
wherein the logic die further comprises a delay circuit configured to delay the second clock signal by a first delay time and output a first delay clock signal, and
wherein the FIFO circuit is further configured to sample the first parallel data and the second parallel data in response to a rising edge of the first delay clock signal.

10. The semiconductor device of claim 8,
wherein the memory device operates using the first clock signal, the second clock signal, a third clock signal having a phase difference of 90 degrees from the first clock signal, and a fourth clock signal having an anti-phase of the third clock signal, and
wherein the logic die receives the first clock signal and the second clock signal from the memory device through at least a portion of the plurality of TSVs.

11. An integrated circuit comprising:
a deserializer configured to output first parallel data based on input data using a first clock signal having a first phase and output second parallel data based on the input data using a second clock signal having a second phase, wherein the first phase is different from the second phase;
a delay circuit configured to delay the second clock signal by a first delay time and output a first delay clock signal; and
a first-in first-out (FIFO) circuit configured to:
sample the first parallel data in response to a rising edge of the first delay clock signal and store the sampled first parallel data as first sampling data,
sample the second parallel data in response to the rising edge of the first delay clock signal and store the sampled second parallel data as second sampling data,
output the first sampling data as first output data in response to a rising edge of a memory clock signal, and
output the second sampling data as second output data in response to the rising edge of the memory clock signal.

12. The integrated circuit of claim 11, further comprising:
a first flip-flop and a second flip-flop,
wherein the first and the second flip-flops are connected to the FIFO circuit,
wherein the first flip-flop is configured to output the first output data as first read data in response to the memory clock signal, and
wherein the second flip-flop is configured to output the second output data as second read data in response to the memory clock signal.

13. The integrated circuit of claim 11, further comprising:
a third flip-flop configured to output a second enable signal based on a first enable signal in response to the memory clock signal; and
a counter circuit configured to count a number of rising edges of the memory clock signal while the second enable signal is maintained at a logic high level,
wherein the FIFO circuit is further configured to output data corresponding to a pointer signal transmitted from the counter circuit.

14. The integrated circuit of claim 11, further comprising:
an input/output circuit configured to receive the input data through a first through-silicon via (TSV),
wherein the input/output circuit is configured to control a voltage level of a signal received through the first TSV.

15. The integrated circuit of claim 14, further comprising:
a first write flip-flop configured to output first write data in response to the rising edge of the memory clock signal;
a second write flip-flop configured to output second write data in response to the rising edge of the memory clock signal; and
a serializer configured to output serial write data based on the first write data and the second write data using a third clock signal,
wherein the input/output circuit is further configured to output the serial write data through a second TSV.

16. A semiconductor device comprising:
a logic die; and
a plurality of memory dies stacked on one surface of the logic die and configured to operate using a plurality of clock signals having different phases,
wherein the logic die comprises:
a deserializer configured to output first parallel data based on input data received from the plurality of memory dies using a first clock signal having a first phase and output second parallel data from the input data using a second clock signal having a second phase, wherein the first phase is different from the second phase;
a delay circuit configured to delay the second clock signal by a first delay time and output a first delay clock signal; and
a first-in first-out (FIFO) circuit configured to:
sample the first parallel data in response to a rising edge of the first delay clock signal and store the sampled first parallel data as first sampling data,
sample the second parallel data in response to the rising edge of the first delay clock signal and store the sampled second parallel data as second sampling data, and
output the first sampling data as first output data and output the second sampling data as second output data in response to a rising edge of a memory clock signal in a FIFO scheme.

17. The semiconductor device of claim 16,
wherein the plurality of memory dies are connected to the logic die through a plurality of through-silicon vias (TSVs), and
wherein the logic die further comprises an input/output circuit configured to receive the input data through a first TSV.

18. The semiconductor device of claim 17,
wherein the second clock signal has an anti-phase of the first clock signal, and
wherein the logic die is configured to obtain the first clock signal and the second clock signal through at least a portion of the plurality of TSVs.

19. The semiconductor device of claim 16,
wherein the logic die further comprises a first flip-flop and a second flip-flop,
wherein the first and the second flip-flops are connected to the FIFO circuit,
wherein the first flip-flop is configured to output the first output data as first read data in response to the memory clock signal, and
wherein the second flip-flop is configured to output the second output data as second read data in response to the memory clock signal.

20. The semiconductor device of claim 19,
wherein the logic die further comprises:
a controller configured execute one or more instructions which cause the controller to read data from the plurality of memory dies,
a third flip-flop configured to output a second enable signal in response to a first enable signal being input from the controller; and
a fourth flip-flop configured to output a valid signal based on the second enable signal in response to the rising edge of the memory clock signal, and
wherein the controller is further configured to execute the one or more instructions which cause the controller to obtain the first read data and the second read data in response to the valid signal being high.
